(19) United States
(12) Patent Application Publication
(10) Pub. No.: US 2019/0284692 A1
(43) Pub. Date: Sep. 19, 2019

(54) REACTOR FOR APPLYING A COATING ON INTERNAL SURFACES OF COMPONENTS

(71) Applicant: Applied Materials, Inc., Santa Clara, CA (US)

(72) Inventors: Yuriy MELNIK, San Jose, CA (US); Sukti CHATTERJEE, San Jose, CA (US); Kaushal GANGAKHEDKAR, San Jose, CA (US); Jonathan FRANKEL, Los Gatos, CA (US); Lance A. SCUDDER, Sunnyvale, CA (US); Pravin K. NARWANKAR, Sunnyvale, CA (US); David Alexander BRITZ, San Jose, CA (US); David Masayuki ISHIKAWA, Mountain View, CA (US)

(21) Appl. No.: 16/356,681

(22) Filed: Mar. 18, 2019

Related U.S. Application Data
(60) Provisional application No. 62/644,645, filed on Mar. 19, 2018.

(51) Int. Cl. C23C 16/455

(52) U.S. Cl. CPC C23C 16/45544; C23C 16/45555

(57) ABSTRACT

A gas distribution assembly for applying a coating on an interior of a plurality of components includes a support with a plurality of component cavities formed within the support. Each component cavity corresponds to a respective component to fluidly couple with an interior of the respective component. A first gas source flow line is fluidly coupled with each of the component cavities to provide a first gas from a first gas source to each of the component cavities, and a second gas source flow line is fluidly coupled with each of the component cavities to provide a second gas from a second gas source to each of the component cavities.

### CROSS-REFERENCE TO RELATED APPLICATION

This application claims the benefit of U.S. Provisional Patent Application Ser. No. 62/644,645 (Attorney Docket 44015332US01) filed Mar. 19, 2018, which is incorporated herein by reference.

### BACKGROUND

### Field

Embodiments of the present disclosure generally relate to a system and apparatus for applying coatings on components. More specifically, embodiments of the present disclosure relate to a reactor for applying one or more coatings on internal surfaces of components.

### Description of the Related Art

Industrial components and tools that are hollow or have internal surfaces defined therethrough are often coated or treated to increase the functionality and lifespan of the components. For example, for an aircraft gas turbine jet engine, air is drawn into the front of the engine, and is then compressed and mixed with fuel. The mixture is burned to form a hot gas that passes through the turbine mounted on a shaft. The flow of the hot gas against the blades and vanes is used to turn the turbine with the hot gas then flowing from the back of the engine and driving the aircraft forward. The blades and vanes are heated by the hot gas and have passageways formed therethrough to facilitate air cooling.

Internal cooling passages are formed within the interior of the blades and vanes so that the components can sustain use above the melting point of the component base material. Air is forced through the component cooling passages and out openings at the external surface, removing heat from the interior surfaces and maintaining the exterior surface temperature below a critical temperature limit. Air in some regions of the World has high levels of industrial particulate emissions and pollutants such as sulfur dioxide. Polluted air, when forced through the component cooling passages, can initiate and accelerate component corrosion. Component corrosion on cooling passage surfaces can adversely affect heat transfer from the component to the cooling air. Excessive component corrosion requires component rework or replacement which increases the jet engine maintenance costs. Coatings and treatments may be used to increase the functionality and lifespan of the turbine components, such as heat treatments or coatings that are heat resistive and that minimize surface oxidation, corrosion, and pitting. However, it may be difficult to effectively apply coatings to the interior of these components, particularly as the geometry of the interior of the components may be fairly complex with high aspect ratios. Accordingly, there is a need to improve the application of coatings to the interior of components.

### SUMMARY

Embodiments of the present disclosure generally relate to a system and apparatus for applying coatings on components. More specifically, embodiments of the present disclosure relate to a reactor for applying one or more coatings on internal surfaces of components.

In one embodiment, a reactor for applying a coating on an interior of a plurality of components includes a gas distribution assembly configured to receive a first gas source and a second gas source and distribute each of a first gas from the first gas source and a second gas from the second gas source to each of a plurality of component cavities formed within the gas distribution assembly. The reactor further includes a gas exhaust assembly configured to couple to the gas distribution assembly, define a reactor chamber therebetween, and exhaust gas from the reactor chamber, and a holder including a plurality of slots formed therein, each slot configured to receive a respective component. The holder with the plurality of components is configured to be received within the reactor chamber such that the interior of each component is fluidly coupled with a respective component cavity.

In another embodiment, a gas distribution assembly for applying a coating on an interior of a plurality of components includes a support with a plurality of component cavities formed within the support, each component cavity corresponding to a respective component to fluidly couple with an interior of the respective component. The gas distribution assembly further includes a first gas source flow line fluidly coupled with each of the component cavities to provide a first gas to each of the component cavities, and a second gas source flow line fluidly coupled with each of the component cavities to provide a second gas to each of the component cavities.

In another embodiment, a gas distribution assembly for applying a coating on an interior of a plurality of components includes a support with a plurality of component cavities formed within the support, each component cavity corresponding to a respective component to fluidly couple with an interior of the respective component. The gas distribution assembly further includes a first gas source flow line fluidly coupled with each of the component cavities to provide a first gas to each of the component cavities, and a purge gas source flow line is fluidly coupled with each of the ports to provide a purge gas to each of the ports.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is an above perspective view of a reactor in accordance with one or more embodiments of the present disclosure.

FIG. 2 is an above exploded view of a reactor in accordance with one or more embodiments of the present disclosure.

FIG. 3 is a below exploded view of a reactor in accordance with one or more embodiments of the present disclosure.

FIG. 4 is an above exploded view of components received within holders for a reactor in accordance with one or more embodiments of the present disclosure.

FIG. 5 is a top down view of a gas distribution assembly in accordance with one or more embodiments of the present disclosure.

FIG. 6 is a detailed above perspective view of a gas distribution assembly in accordance with one or more embodiments of the present disclosure.

FIG. 7 is a side view of a reactor in accordance with one or more embodiments of the present disclosure.

FIG. 8 is a cross-sectional view of the reactor taken along line 8-8 referenced in FIG. 5 in accordance with one or more embodiments of the present disclosure.

FIG. 9 is a bottom view of a gas distribution assembly in accordance with one or more embodiments of the present disclosure.

FIG. 10 is a detailed view of the gas distribution assembly referenced in FIG. 9 in accordance with one or more embodiments of the present disclosure.

FIG. 11 is a detailed cross-sectional view of the reactor taken along line 11-11 referenced in FIG. 10 in accordance with one or more embodiments of the present disclosure.

FIG. 12 is a detailed cross-sectional view of the reactor taken along line 12-12 referenced in FIG. 10 in accordance with one or more embodiments of the present disclosure.

FIG. 13 is a detailed cross-sectional view of the reactor taken along line 13-13 referenced in FIG. 10 in accordance with one or more embodiments of the present disclosure.

FIG. 14 is a detailed cross-sectional view of the reactor taken along line 14-14 referenced in FIG. 10 in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a reactor and a method for applying a coating on an interior of a plurality of components. The reactor includes a gas distribution assembly and a gas exhaust assembly that are able to couple to each other (e.g., open and close with respect to each other) and define a reactor chamber therebetween. The gas distribution assembly is used to receive one or more gas sources and distribute the gas sources within the reactor chamber, and the gas exhaust assembly is used to exhaust gas from the reactor chamber. In particular, the gas distribution assembly includes a plurality of component cavities formed within the gas distribution assembly with a component corresponding to each respective component cavity. The gas distribution assembly is used to distribute a first gas source (and potentially a second gas source) to each of the component cavities within the gas distribution assembly. Further, the gas distribution assembly is used to receive a purge gas source and distribute the purge gas source exterior to the component cavities and into the reactor chamber.

The components, when received within the reactor chamber, each fluidly couple with a respective component cavity. For example, an insert may be removably positioned within each respective component cavity to facilitate fluidly coupling and sealing the component with the component cavity. A holder is used to secure the plurality of components within the reactor chamber. The holder includes a plurality of slots formed therein with a component received within each respective slot. The holder may include one or more securing members to secure the components within the slots, and may be used with one or more alignment members to align the holder within the reactor chamber. Further, one or more heaters are included within the reactor to control a temperature of the components and the gases within the reactor chamber.

The reactor may be used to apply or deposit one or more layers or coatings on the interior of the components, such as through an atomic layer deposition (ALD) process. The reactor may enable the layers or coatings, through the gases, to be applied to the interior of the components while under vacuum. ALD is based upon atomic layer epitaxy (ALE) and employs chemisorption techniques to deliver precursor molecules on a surface in sequential cycles. The cycle exposes the surface to a first precursor and then to a second precursor. Optionally, a purge gas may be introduced between introductions of the precursors. The first and second precursors react to form a product compound as a film on the substrate surface. The cycle is repeated to form the layer or coating to a desired thickness.

Embodiments of the present disclosure include a reactor that is operable to perform a deposition process to form one or more layers or coatings on an interior of one or more components. The layers deposited by the reactor may include, for example, aluminum oxide (Al₂O₃) or silicon nitride (SiN). The embodiments described herein may be used with various types, shapes, and sizes of components. The components are not limited to any particular size or shape. In one aspect, the term “component” refers to a workpiece having any size or shape, and may include any type of material, such as metal, glass, or polymer. In the description that follows, the terms “gas” and “gases” are used interchangeably, unless otherwise noted, and refer to one or more precursors, reactants, catalysts, carrier gases, purge gases, cleaning gases, effluent, combinations thereof, as well as any other fluid.

Further, in one embodiment, the ALD process generally takes place at temperatures from about room temperature to 300° C. by alternating doses of precursors with oxidizers. Precursors are generally dosed into the reactor in either static mode or flow-through mode. In static mode, reactants are pulsed into the reactor and allowed to dwell in the reactor until consumed. Reaction byproducts are then pumped out and the reactant is pulsed again until all reaction sites on the component have been occupied. The reactor is then purged of residual reactant by a flow of an inert gas, which may or may not be heated or ionized to enhance efficiency of the purge. The cycle is then repeated with the second reactant. In flow-through mode, the flow rate of the reactant is set such that it is fully or nearly fully consumed in the reactor without closing the reactor exhaust. Flow rates or precursor doping of a carrier flow can be controlled in closed-loop fashion by monitoring exhaust composition or gas composition in the reactor. The flow rate of the reactant can be minimized to reduce coating costs due to chemical consumption and coating time duration.

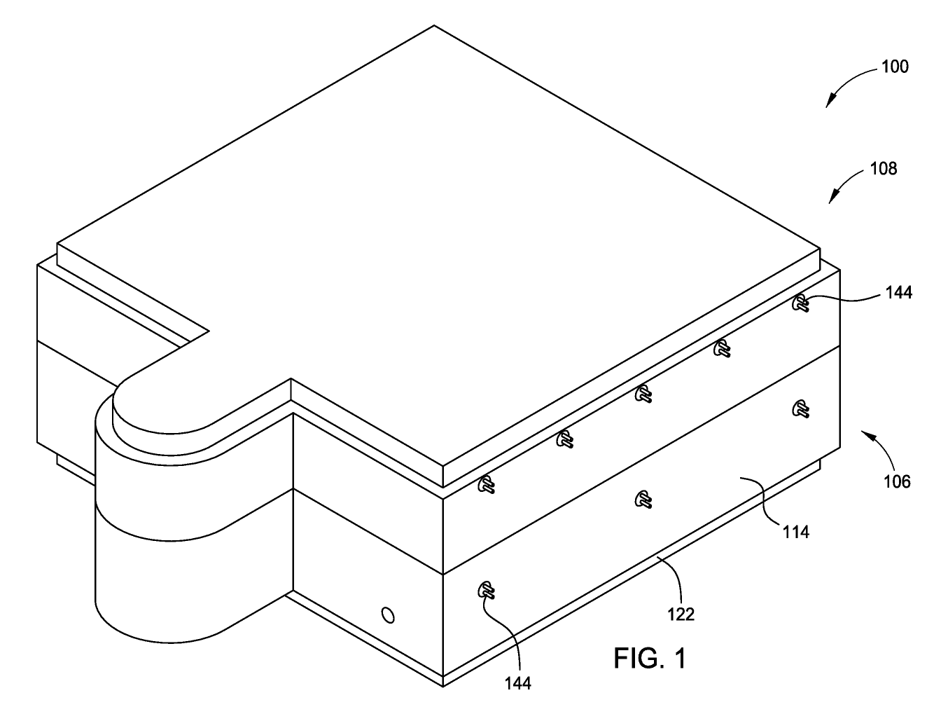

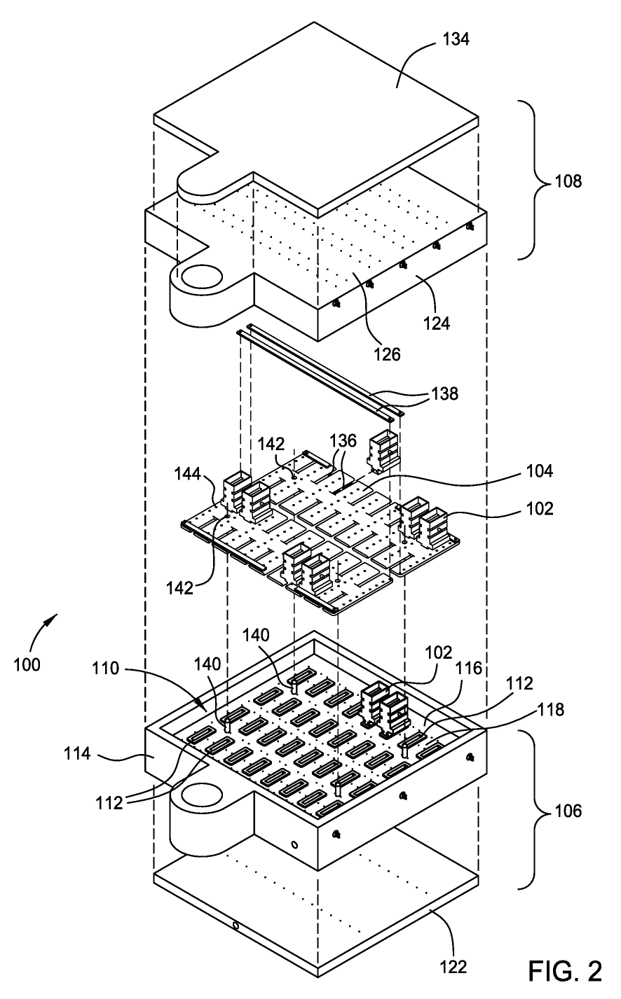

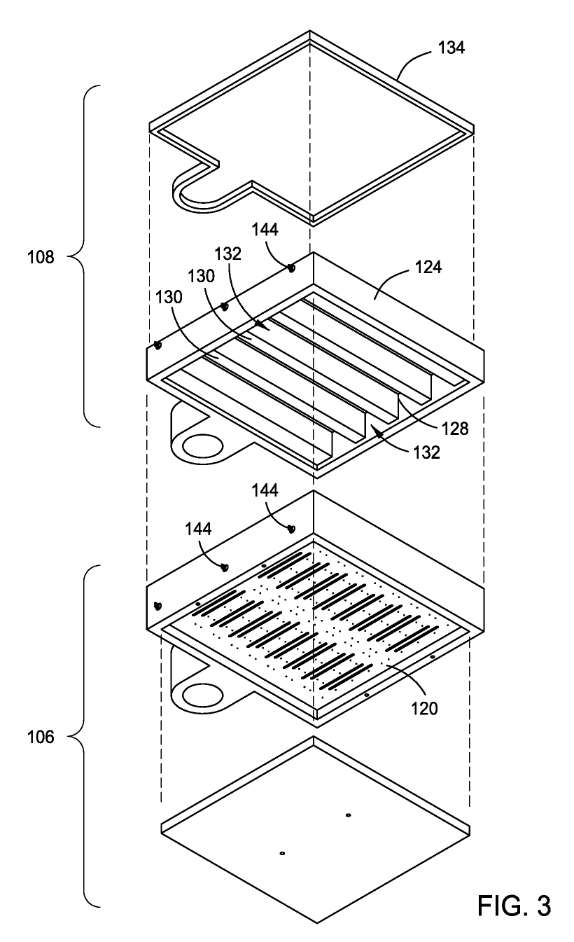

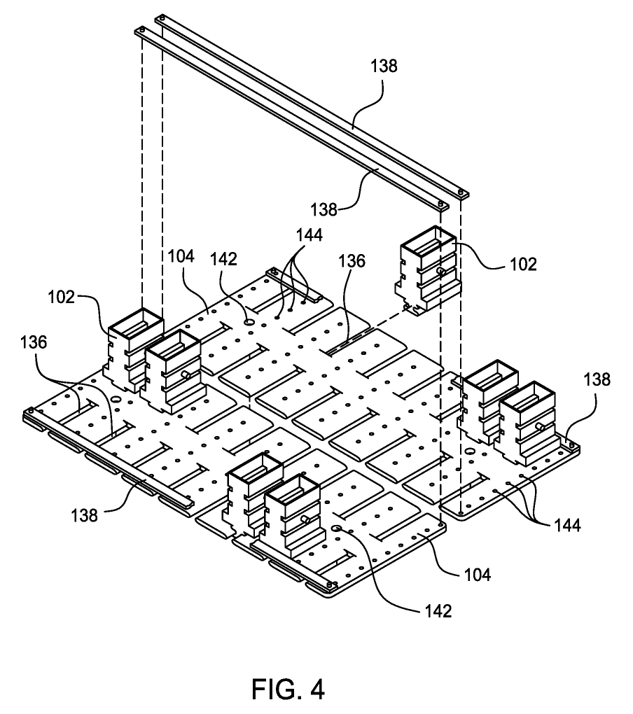

Referring now to FIGS. 1-4, multiple views of a reactor 100 for applying one or more coatings to an interior of one or more components 102 in accordance with one or more embodiments are shown. In particular, FIG. 1 shows an above perspective view of the reactor 100, FIG. 2 shows an above exploded view of the reactor 100 with the components 102, FIG. 3 shows a below exploded view of the reactor 100, and FIG. 4 shows an above exploded view of the components 102 received within holders 104.

The reactor 100, as shown, includes a gas distribution assembly 106 and a gas exhaust assembly 108 that are able to couple to each other (e.g., open and close with respect to each other). When coupled to each other, the gas distribution assembly 106 and the gas exhaust assembly 108 seal against each other to define a reactor chamber 110 therebetween. The gas distribution assembly 106 has one or more component cavities 112 formed therein, such as with each component cavity 112 corresponding to a component 102. A component 102 is able to fluidly couple with a respective component cavity 112. The components 102 have an interior and may be hollow or have passageways formed therein. When a component 102 is fluidly coupled with the component cavity 112, gas or fluid from the component cavity 112 may be able to flow into (or through) the interior of the component 102.

The gas distribution assembly 106 includes a body 114 with a support 116 or support plate. The support 116 has an upper surface 118, shown best in FIG. 2, and a lower surface 120, shown best in FIG. 3. The component cavities 112 are formed within the support 116, such as formed within the upper surface 118 of the support 116. The gas distribution assembly 106 is further shown as having a lower plate 122 that couples to the body 114 or the support 116. The lower plate 122 is spaced from the support 116, such as from the lower surface 120, to define a gas distribution chamber (discussed more below) between the support 116 and the lower plate 122.

The gas distribution assembly 106 receives and is used to distribute one or more gas sources to each of the component cavities 112. For example, a first gas source flow line and a second gas source flow line, each discussed more below, may be formed at least partially within the gas distribution assembly 106 to each fluidly couple with each of the components cavities 112. A first gas from a first gas source is provided through the first gas source flow line to each component cavity 112, and a second gas from a second gas source is provided through the second gas source flow line to each component cavity 112. The first and second gas source flow lines are separate and distinct from each other such that the first gas and the second gas are not capable of mixing before or upstream of the component cavities 112.

Further, the gas distribution assembly 106 receives and is used to distribute one or more gas sources exterior to the component cavities 112. For example, a purge gas source flow line may be formed at least partially within the gas distribution assembly 106, is fluidly coupled with the reactor chamber 110 but is fluidly decoupled from the component cavities 112. A purge gas from a purge gas source is provided through the purge gas source flow line around the component cavities 112 and into the reactor chamber 110. The purge gas source flow line is separate and distinct from the first and second gas source flow lines such that the purge gas is not capable of mixing with other gases before or upstream of the reactor chamber 110.

The gas exhaust assembly 108 includes a body 124 that has an upper surface 126, shown best in FIG. 2, and a lower surface 128, shown best in FIG. 3. The lower surface 128 of the body 124 includes one or more partitions 130 formed therein, such as to define sub-chambers 132 within the reactor chamber 110. The components 102 may be positioned within the sub-chambers 132 when received within the reactor chamber 110 of the reactor 100. The sub-chambers 132 may be tailored to conform to the specific component 102 shape to minimize the total reactor chamber 110 volume and to avoid stagnation zones. The gas exhaust assembly 108 is shown as further including an upper plate 134 that couples to the body 124. The upper plate 134 is spaced from the body 124, such as from the upper surface 126 in some portions, to define a gas exhaust chamber (discussed more below) between the body 124 and the upper plate 134.

The gas exhaust assembly 108 is used to exhaust gas from the reactor chamber 110 of the reactor 100. As discussed above, gas, such as a first gas and a second gas, are provided to the component cavities 112 to flow into the interior of the components 102. This gas may then flow through and out of the components 102 and into the reactor chamber 110. Purge gas may also be provided into the reactor chamber 110, such as exterior to the components 102, to facilitate the flow of gas within the reactor chamber 110. The first gas, the second, and/or the purge gas in the reactor chamber 110 may then be exhausted through the gas exhaust assembly 108. For example, a gas exhaust flow line may be formed at least partially within the gas exhaust assembly 108 to exhaust the gas from the reactor chamber 110 and through the gas exhaust assembly 108. Further, a vacuum source may be fluidly coupled with the gas exhaust flow line to facilitate flow and exhausting of the gas through the gas exhaust flow line.

Referring still to FIGS. 1-4, and as best shown in FIGS. 2 and 4, the reactor 100 includes one or more holders 104 to position and receive the components 102 within the reactor chamber 110. The holder 104 includes one or more slots 136 formed therein, such as with each slot 136 corresponding to a component 102. A component 102 is then removably received within the slot 136, such as by having the component 102 slidingly or laterally received into the slot 136 with the slot 136 engaging the component 102. Further, one or more securing members 138 may be removably coupled to the holder 104 to secure the components 102 within the slots 136. The securing members 138 are shown as bars that extend across the opening of the slots 136 to prevent the components 102 from moving with respect to or through the opening of the slots 136. A securing member 138 may be secured to the holder 104 through one or more fasteners, such as a screw, bolt, or clip, that engage the securing member 138 and the holder 104.

With the components 102 received within the slots 136 of the holder 104, the holder 104 is then received within the reactor chamber 110 to align the components 102 with respect to the component cavities 112 and secure the components 102 within the reactor chamber 110. The components 102 align with the component cavities 112 using the holder 104 such that the components 102 are able to fluidly couple with the component cavities 112. Further, one or more alignment members 140 may be used to align the holder 104 within the reactor chamber 110 or with respect to the gas distribution assembly 106. For example, alignment members 140, such as rods or extensions, may be positioned or secured to the support 116 of the gas distribution assembly 106 and extend upward from the upper surface 118. The alignment members 140 may be received within and engage holes 142 formed within the holders 104 to align the holders 104 with respect to the support 116, and therefore the components 102 with respect to the component cavities 112.

Furthermore, the holders 104 may have one or more apertures 144 formed therethrough. The apertures 144 may extend through the holders 104 to facilitate gas flow therethrough and within the reactor chamber 110. In particular, the apertures 144 may be used to facilitate the flow of the purge gas through the holders 104 and around the components 102.

In one or more embodiments, one or more heaters 146 may be included within the reactor 100, such as to selectively control the temperature of the components 102, gases, and/or reactions within the reactor chamber 110. For example, one or more heaters 146 may be positioned within the gas distribution assembly 106, such as positioned within and extending through the support 116 of the gas distribution assembly 106. One or more heaters 146 may also be positioned within the gas exhaust assembly 108, such as positioned within and extending through the partitions 130 of the body 124 of the gas exhaust assembly 108.

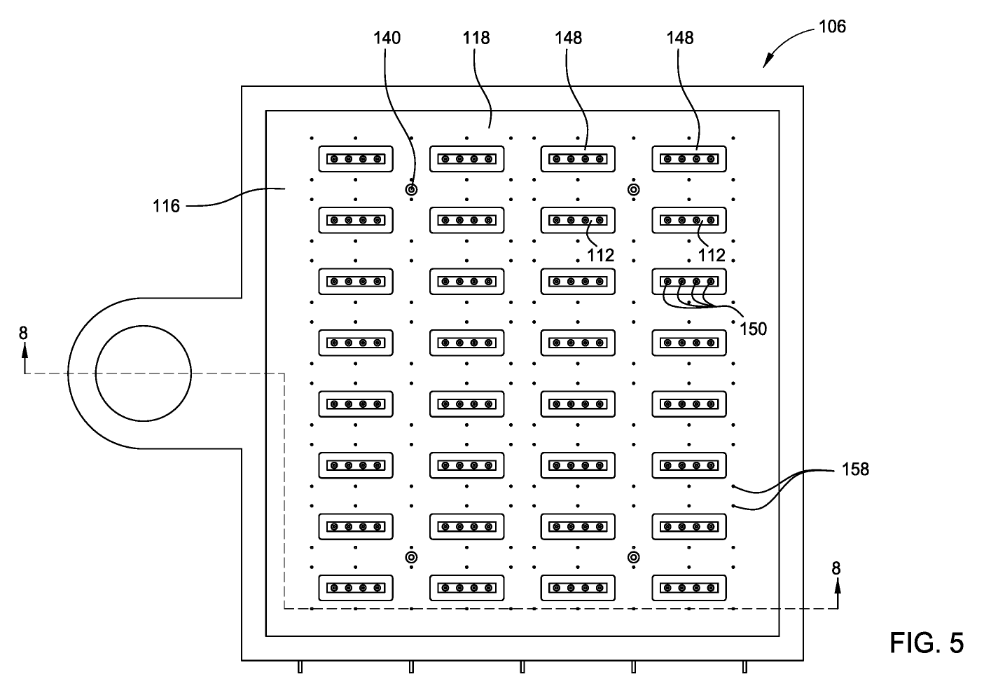

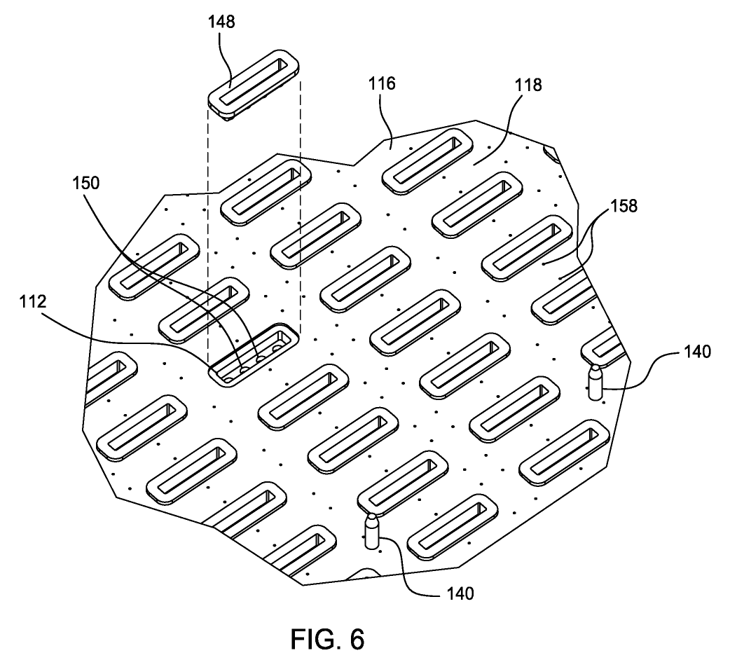

Referring now to FIGS. 5 and 6, multiple views of the gas distribution assembly 106 in accordance with one or more embodiments of the present disclosure are shown. In particular, FIG. 5 shows a top down view of the gas distribution assembly 106, and FIG. 6 shows a detailed above perspective view of the gas distribution assembly 106.

The gas distribution assembly 106 includes one or more component cavities 112 formed within the upper surface 118 of the support 116, in which a component 102 is able to fluidly couple with each respective component cavity 112. One or more inserts 148 may be included within the gas distribution assembly 106 to facilitate fluidly coupling the components 102 to the component cavities 112. For example, an insert 148 may correspond to each component cavity 112 with the insert 148 removably received within the component cavity 112. The component 102 may then engage (e.g., directly contact) the insert 148 when fluidly coupling with the respective component cavity 112.

For example, the component 102 may form a seal against the insert 148, and the insert 148 may form a seal within the component cavity 112, to fluidly couple the component 102 with the component cavity 112. The inserts 148 may include or be formed from an elastomeric material, such as Viton™ or Kalrez®. The inserts 148 may be made from a plastic, ceramic or metal material, such as Teflon™, graphite, aluminum or stainless steel. The inserts 148 may coat at a slower rate than the component 102 or may be easier to clean than support 116 to minimize maintenance time and expense. Further, the component cavities 112 may each include one or more ports 150 formed therein, such as to provide the first gas and the second gas through the support 116 and into the component cavities 112. In one or more embodiments, the inserts 148 may each include one or more ports formed therein as well, corresponding to the ports 150 of the component cavities 112 to align with the ports 150. The ports formed within each insert 148 facilitate fluid flow through the component cavity 112 and into the respective component 102. The ports formed within each insert 148 can have an equal diameter or smaller diameter than a diameter of ports 150 of the component cavities 112 to restrict the flow of the first gas and the second gas into the respective component 102. Restricting flow into the component 102 can facilitate flow balancing over the support 116 and minimize gas back-diffusion into first and second gas source flow lines 152, 154. Further, the ports formed within each insert 148 can be chamfered at the outlet to form a divergent nozzle that reduces the gas velocity into the component cavities 112 and minimizes stagnant volumes upstream of the component 102 inlet.

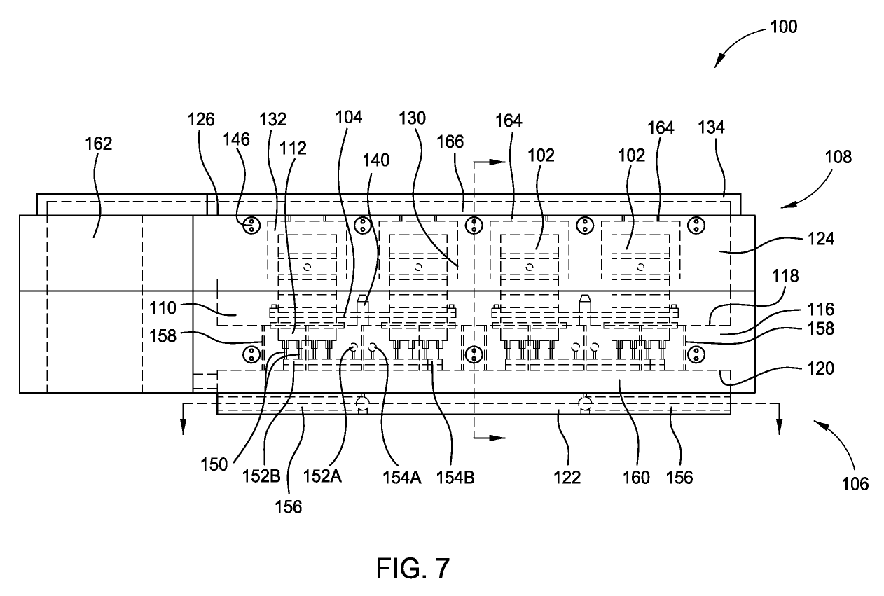

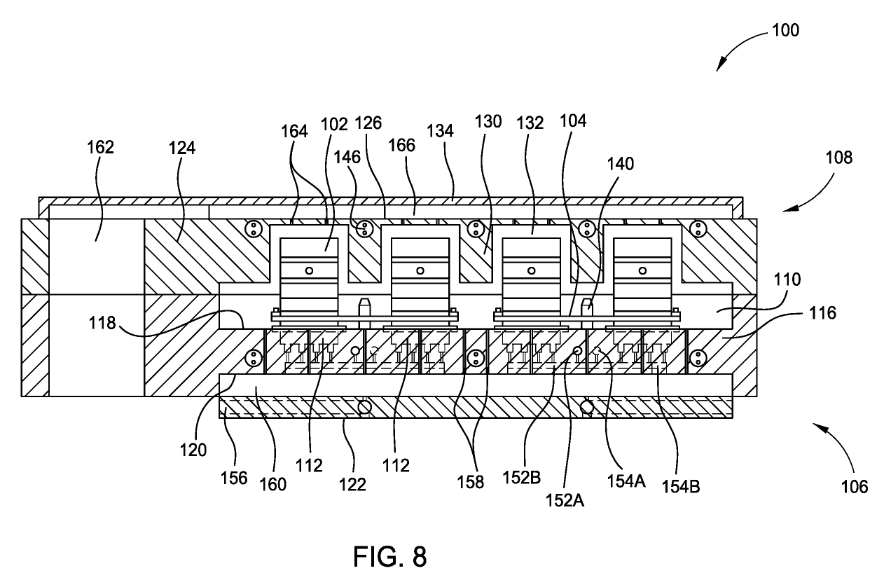

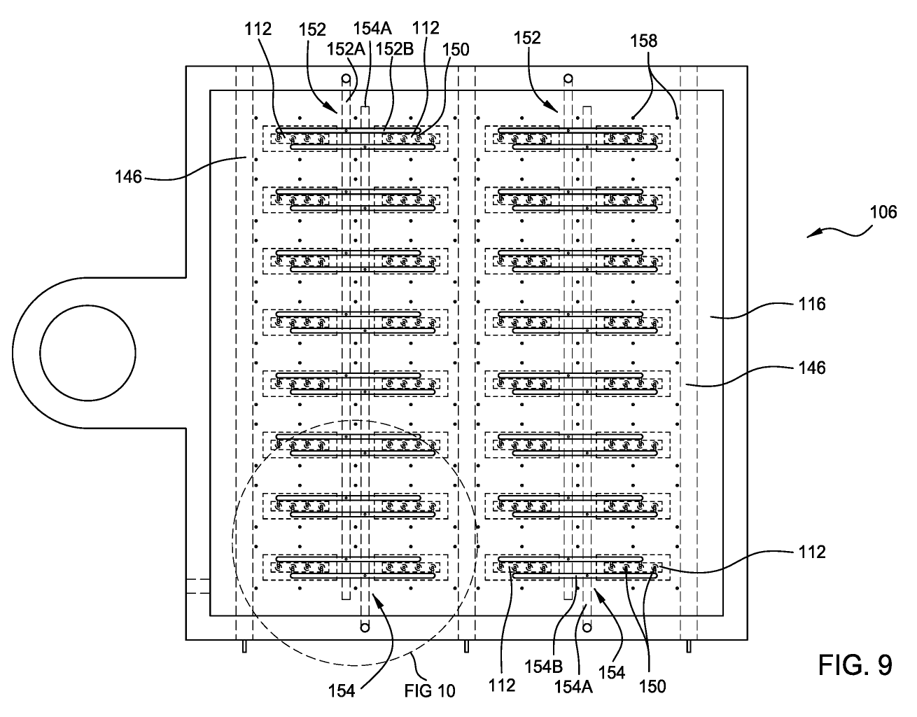

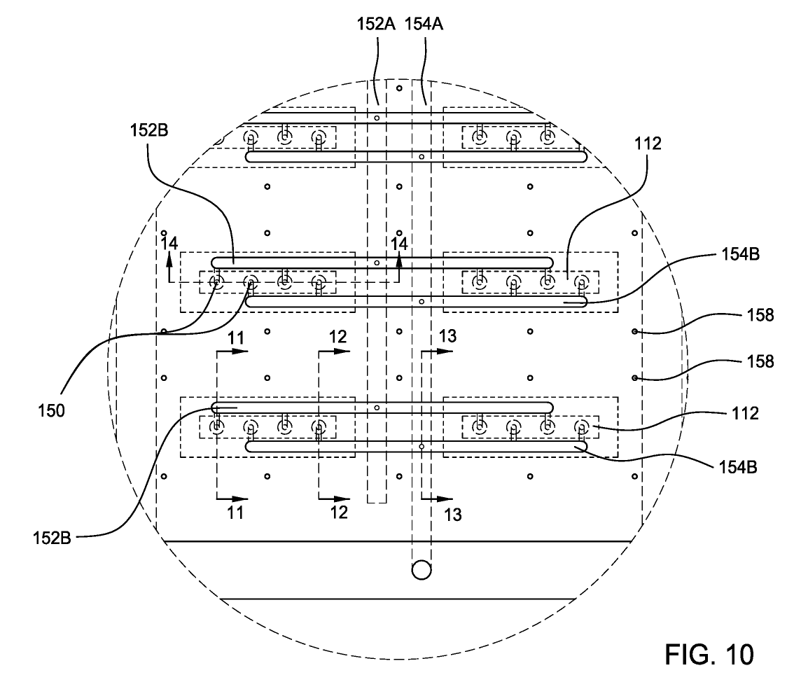

Referring now to FIGS. 7-10, multiple views of the reactor 100 and the gas distribution assembly 106 in accordance with one or more embodiments of the present disclosure are shown. In particular, FIG. 7 shows a side view of the reactor 100 with internal passages of the reactor 100 in dashed or ghosted lines, FIG. 8 shows a cross-sectional view of the reactor 100 taken along line 8-8 referenced in FIG. 5, FIG. 9 shows a bottom view of the gas distribution assembly 106 with internal passages of the gas distribution assembly 106 in dashed or ghosted lines, and FIG. 10 shows a detailed view of the gas distribution assembly 106 referenced in FIG. 9.

As discussed above, the gas distribution assembly 106 includes one or more first gas source flow lines 152 formed therein and one or more second gas source flow lines 154 formed therein. The first gas source flow line 152 fluidly couples with the component cavities 112 to provide a first gas from a first gas source to the component cavities 112. Further, the second gas source flow line 154 fluidly couples with the component cavities 112 to provide a second gas from a second gas source to the component cavities 112.

The first gas source flow line 152 is formed (at least partially) within the gas distribution assembly 106, and more particularly the support 116, to fluidly couple with the component cavities 112. As shown in FIGS. 7-10, the first gas source flow line 152 includes one or more primary channels 152A with one or more auxiliary channels 152B fluidly coupled to the primary channels 152A. Further, the auxiliary channels 152B fluidly couple with one or more of the component cavities 112. For example, as best shown in FIG. 9, multiple primary channels 152A are formed within the support 116 and extend substantially across the width of the gas distribution assembly 106. The primary channels 152A are shown as extending between sets or rows of the component cavities 112. Multiple auxiliary channels 1526 are formed within the support 116 to fluidly couple with each primary channel 152A. As shown, the auxiliary channels 1526 are positioned transverse to the primary channels 152A.

The auxiliary channels 152B fluidly couple to one or more component cavities 112, such as with each auxiliary channel 1526 extending between and fluidly coupling with two component cavities 112. The ports 150 are formed between each auxiliary channel 152B and component cavity 112 to fluidly couple the auxiliary channel 152B with the component cavity 112. Thus, in this configuration, the first gas source flow line 152 includes multiple auxiliary channels 152B fluidly coupled with each primary channel 152A. A first gas from a first gas source is able to be provided through the first gas source flow line 152 to each of the component cavities 112.

Similarly, the second gas source flow line 154 is formed (at least partially) within the gas distribution assembly 106, and more particularly the support 116, to fluidly couple with the component cavities 112. As shown in FIGS. 7-10, the second gas source flow line 154 includes one or more primary channels 154A with one or more auxiliary channels 154B fluidly coupled to the primary channels 154A. Further, the auxiliary channels 154B fluidly couple with one or more of the component cavities 112. For example, as best shown in FIG. 9, multiple primary channels 154A are formed within the support 116 and extend substantially across the width of the gas distribution assembly 106. The primary channels 154A are shown as extending between sets or rows of the component cavities 112. Multiple auxiliary channels 1546 are formed within the support 116 to fluidly couple with each primary channel 154A. As shown, the auxiliary channels 154B are positioned transverse to the primary channels 154A.

The auxiliary channels 154B fluidly couple to one or more component cavities 112, such as with each auxiliary channel 1546 extending between and fluidly coupling with two component cavities 112. The ports 150 are formed between each auxiliary channel 154B and component cavity 112 to fluidly couple the auxiliary channel 154B with the component cavity 112. Thus, in this configuration, the second gas source flow line 154 includes multiple auxiliary channels 154B fluidly coupled with each primary channel 154A. A second gas from a second gas source is able to be provided through the second gas source flow line 154 to each of the component cavities 112.

Referring still to FIGS. 7-10, and as discussed above, the gas distribution assembly 106 receives and is used to distribute one or more gas sources exterior to the component cavities 112. For example, a purge gas from a purge gas source is provided, such as through a purge gas source flow line 156, around the component cavities 112 and into the reactor chamber 110. The purge gas source flow line 156 may be formed at least partially within the gas distribution assembly 106, and is fluidly coupled with the reactor chamber 110 but is fluidly decoupled from the component cavities 112. The purge gas source flow line 156 is separate and distinct from the first and second gas source flow lines 152 and 154 such that the purge gas is not capable of mixing with other gases before or upstream of the reactor chamber 110.

As shown, the support 116 of the gas distribution assembly 106 includes one or more ports 158 formed therein or therethrough that are exterior to or fluidly decoupled from the component cavities 112. The ports 158 are formed within the support 116 to extend from the upper surface 118 to the lower surface 120 of the support 116. Further, the gas distribution assembly 106 includes a gas distribution chamber 160 with the ports 158 fluidly coupled with the gas distribution chamber 160 through the support 116. In this embodiment, the lower plate 122 is coupled to the body 114 of the gas distribution assembly 106 to define the gas distribution chamber 160 between the support 116 and the lower plate 122. Furthermore, the purge gas source flow line 156 is formed within the lower plate 122. Thus, purge gas from the purge gas source may be provided through the purge gas source flow line 156 into the gas distribution chamber 160. The purge gas may then follow from the gas distribution chamber 160 and through the ports 158 into the reactor chamber 110 and exterior to the component cavities 112.

In one or more embodiments, the gas exhaust assembly 108 is used to exhaust gas from the reactor chamber 110 of the reactor 100. As discussed above, gas, such as a first gas and a second gas, are provided to the component cavities 112 to flow into the interior of the components 102. This gas may then flow through and out of the components 102 and into the reactor chamber 110. Further, purge gas is also provided into the reactor chamber 110, such as exterior to the components 102, to facilitate the flow of gas within the reactor chamber 110. The first gas, the second, and/or the purge gas in the reactor chamber 110 are exhausted through the gas exhaust assembly 108. For example, a gas exhaust flow line 162 may be formed at least partially within the gas exhaust assembly 108 to exhaust the gas from the reactor chamber 110 and through the gas exhaust assembly 108. Further, a vacuum source may be fluidly coupled with the gas exhaust flow line 162 to facilitate flow and exhausting of the gas through the gas exhaust flow line 162.

As shown, the body 124 of the gas exhaust assembly 108 includes one or more ports 164 formed therein or therethrough. The ports 164 are formed within the body 124 to extend from the lower surface 128 to the upper surface 126 of the body 124. Further, the gas exhaust assembly 108 includes a gas exhaust chamber 166 with the ports 164 fluidly coupled with the gas exhaust chamber 166 through the body 124. In this embodiment, the upper plate 134 is coupled to the body 124 of the gas exhaust assembly 108 to define the gas exhaust chamber 166 between the body 124 and the upper plate 134.

Furthermore, the gas exhaust flow line 162 is formed within the body 124 of the gas exhaust assembly 108 and is fluidly coupled with the gas exhaust chamber 166. Thus, gas may be exhausted from the reactor chamber 110 through the ports 164 and into the gas exhaust chamber 166, and may follow from the gas exhaust chamber 166 and through the gas exhaust flow line 162 to be exhausted from the reactor 100.

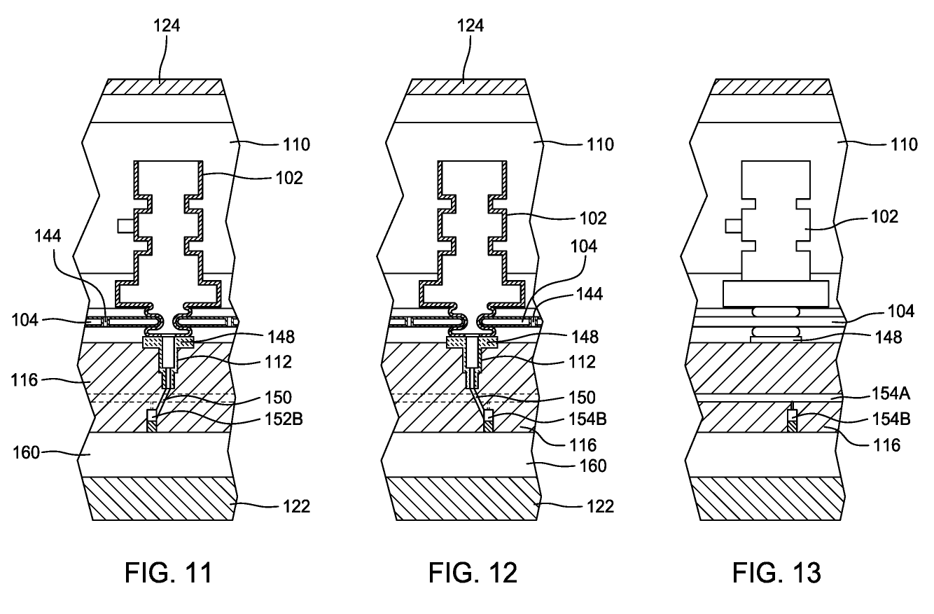

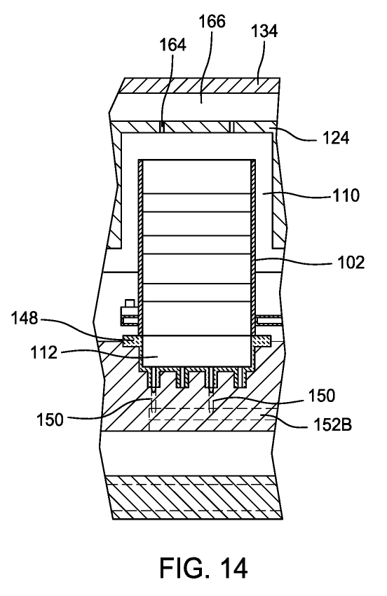

Referring now to FIGS. 11-14, multiple cross-sectional views across portions of the reactor 100 in accordance with one or more embodiments of the present disclosure are shown. In particular, the cross-sectional views in FIGS. 11-14 are referenced within FIG. 10. FIGS. 11 and 14 show detailed cross-sectional views of the auxiliary channel 152B of the first gas source flow line 152. The auxiliary channel 152B is fluidly coupled to the component cavity 112 through one or more ports 150. The insert 148 is positioned within the component cavity 112 to facilitate the fluid coupling between the component 102 and the component cavity 112. Gas provided through the auxiliary channel 152B is able to flow through the port 150 and into the component cavity 112. The gas is able to continue to flow into the interior of the component 102 and out of the component 102 into the reactor chamber 110. Furthermore, gas in the reactor chamber 110 is able to exhaust out of the reactor 100 by further flowing through the ports 164 and into the gas exhaust chamber 166. Similarly, FIGS. 12 and 13 show detailed cross-sectional views of the primary channel 154A and the auxiliary channel 154B of the second gas source flow line 154. The auxiliary channel 154B is fluidly coupled to the component cavity 112 through one or more ports 150. Gas provided through the primary channel 154A is able to flow to the auxiliary channel 154B, further is able to flow through the port 150 and into the component cavity 112.

As discussed above, the reactor in accordance with the present disclosure may be used to apply or deposit one or more layers or coatings on the interior of one or more components through an ALD process. Thus, one or more precursor gases may be provided through the reactor to form or apply the coatings on the interior of the components. In one embodiment, the first gas or first gas source may be a first precursor gas such that the first gas source flow line is used to provide the first precursor gas. Similarly, the second gas or second gas source may be a second precursor gas such that the second gas source flow line is used to provide the second precursor gas. The first precursor gas may include an aluminum precursor gas, a silicon precursor gas, a chromium precursor gas, a titanium precursor gas, and/or a hafnium precursor gas. The second precursor gas may include an oxygen precursor gas. Thus, the first precursor gas and the second precursor gas may be able to combine within the component cavity, and/or within the interior of the component, to form or apply a coating on the interior of the component. Furthermore, the purge gas source may include a nitrogen purge gas, an argon purge gas, and/or a helium purge gas.

In one or more embodiments, one or more valves may be used with or included within the reactor without departing from the scope of the present disclosure. For example, one or more valves may be included within the first gas source flow line, the second gas source flow line, and/or the purge gas source flow line. In one embodiment, a valve may be fluidly coupled with each primary channel of the first gas source flow line and/or the second gas source flow line. In such an embodiment, the flow of the gas may be controlled within each primary channel of the reactor to selectively control the application of the first gas and the second gas within the component cavities of the reactor chamber.

While the foregoing is directed to embodiments of the present disclosure, other and further embodiments of the disclosure may be devised without departing from the basic scope thereof, and the scope thereof is determined by the claims that follow.

What is claimed is:

1. A reactor for applying a coating on an interior of a plurality of components, comprising:
a gas distribution assembly configured to receive a first gas from a first gas source and a second gas from a second gas source and distribute each of the first gas and the second gas to each of a plurality of component cavities formed within the gas distribution assembly;
a gas exhaust assembly configured to couple to the gas distribution assembly, define a reactor chamber therebetween, and exhaust gas from the reactor chamber; and
a holder comprising a plurality of slots formed therein, each slot configured to receive a respective component, the holder with the plurality of components configured to be received within the reactor chamber such that the interior of each component is fluidly coupled with a respective component cavity.

2. The reactor of claim 1, wherein the gas distribution assembly comprises:
a support comprising the plurality of component cavities formed within the support;
a first gas source flow line fluidly coupled with each of the component cavities to provide the first gas to each of the component cavities; and
a second gas source flow line fluidly coupled with each of the component cavities to provide the second gas to each of the component cavities.

3. The reactor of claim 2, wherein:
the first gas source flow line is formed within the support and comprises a primary channel and a plurality of auxiliary channels;
the auxiliary channels are fluidly coupled with the primary channel; and
each auxiliary channel is fluidly coupled with at least one of the component cavities.

4. The reactor of claim 3, wherein:
the second gas source flow line is formed within the support and comprises a primary channel and a plurality of auxiliary channels;
the auxiliary channels are fluidly coupled with the primary channel; and
each auxiliary channel is fluidly coupled with at least one of the component cavities.

5. The reactor of claim 2, wherein the gas distribution assembly is configured to receive a purge gas from a purge gas source and distribute the purge gas exterior to the component cavities and into the reactor chamber.

6. The reactor of claim 5, wherein:
the support further comprises a plurality of ports formed therein and exterior to the component cavities; and
a purge gas source flow line is fluidly coupled with each of the ports to provide the purge gas to each of the ports.

7. The reactor of claim 6, wherein:
the gas distribution assembly further comprises a lower plate coupled to the support and defining a gas distribution chamber between the support and the lower plate;
the purge gas source flow line is formed within the lower plate to provide the purge gas to the gas distribution chamber; and
the plurality of ports are formed within the support to provide the purge gas from the gas distribution chamber to the reactor chamber.

8. The reactor of claim 1, wherein:
the gas exhaust assembly comprises a body and an upper plate coupled to the body and defining a gas exhaust chamber between the body and the upper plate;
a plurality of ports are formed within the body to provide gas from the reactor chamber to the gas exhaust chamber; and
a gas exhaust flow line is formed within the upper plate to exhaust gas from the gas exhaust chamber.

9. The reactor of claim 1, further comprising a plurality of inserts, each insert corresponding to and configured to be removably inserted into a respective component cavity to fluidly couple each component cavity with the respective component.

10. The reactor of claim 1, wherein:
the holder further comprises a plurality of apertures formed therethrough to facilitate gas flow through the holder and a securing member removably coupled thereto to secure the components within the slots; and
the gas distribution assembly further comprises an alignment member to align the holder within the reactor chamber.

11. The reactor of claim 1, further comprising a heater disposed within the gas distribution assembly or the gas exhaust assembly.

12. A gas distribution assembly for applying a coating on an interior of a plurality of components, comprising:
a support comprising a plurality of component cavities formed within the support, each component cavity corresponding to a respective component to fluidly couple with an interior of the respective component;
a first gas source flow line fluidly coupled with each of the component cavities to provide a first gas to each of the component cavities; and
a second gas source flow line fluidly coupled with each of the component cavities to provide a second gas to each of the component cavities.

13. The gas distribution assembly of claim 12, wherein:
the support further comprises a plurality of ports formed therein and exterior to the component cavities; and
a purge gas source flow line is fluidly coupled with each of the ports to provide a purge gas to each of the ports.

14. The gas distribution assembly of claim 13, wherein:
the gas distribution assembly further comprises a lower plate coupled to the support and defining a gas distribution chamber between the support and the lower plate;
the purge gas source flow line is formed within the lower plate to provide the purge gas to the gas distribution chamber; and
the plurality of ports are formed within the support to provide the purge gas from the gas distribution chamber to a reactor chamber.

15. The gas distribution assembly of claim 12, wherein:
the first gas source flow line is formed within the support and comprises a primary channel and a plurality of auxiliary channels;
the auxiliary channels are fluidly coupled with the primary channel; and
each auxiliary channel is fluidly coupled with at least one of the component cavities.

16. The gas distribution assembly of claim 15, wherein each auxiliary channel is fluidly coupled with at least two of the component cavities.

17. The gas distribution assembly of claim 12, further comprising a plurality of inserts, each insert corresponding to and configured to be removably inserted into a respective component cavity to fluidly couple each component cavity with the respective component.

18. A gas distribution assembly for applying a coating on an interior of a plurality of components, comprising:
a support comprising a plurality of component cavities formed within the support and a plurality of ports formed within the support and exterior to the component cavities, each component cavity corresponding to a respective component to fluidly couple with an interior of the respective component;
a first gas source flow line fluidly coupled with each of the component cavities to provide a first gas to each of the component cavities; and
a purge gas source flow line is fluidly coupled with each of the ports to provide a purge gas to each of the ports.

19. The gas distribution assembly of claim 18, further comprising a second gas source flow line fluidly coupled with each of the component cavities to provide a second gas to each of the component cavities.

20. The gas distribution assembly of claim 18, wherein the first gas source flow line and the purge gas source flow line are formed within the support.
